(19) United States
(12) Patent Application Publication
(10) Pub. No.: US 2026/0206256 A1
(43) Pub. Date: Jul. 16, 2026

(54) TRANSISTOR DEVICE AND METHOD FOR PRODUCING THEREOF

(71) Applicant: Infineon Technologies AG, Neubiberg (DE)

(72) Inventors: Fabian RASINGER, Villach (AT); Ravi Keshav JOSHI, Klagenfurt am Wörthersee (AT); Dethard PETERS, Höchstadt (DE); Markus BENINGER-BINA, Aying (DE)

(21) Appl. No.: 19/448,682

(22) Filed: Jan. 14, 2026

(30) Foreign Application Priority Data
Jan. 16, 2025 (DE) 102025101520.1

(51) Int. Cl. H10D 30/66; H10D 30/01; H10D 62/10; H10D 64/00; H10D 84/00

(52) U.S. Cl. CPC H10D 30/665; H10D 30/0297; H10D 30/668; H10D 62/109; H10D 64/117; H10D 84/144

(57) ABSTRACT

A transistor device and a method for producing a transistor device are disclosed. The transistor device includes a semiconductor body; a drift regionof a first doping type in the semiconductor body; a gate padformed above a first surfaceof the semiconductor body; a shielding structurearranged between the gate padand the drift regionand comprising a plurality of shielding electrodeseach arranged in a respective shielding trenchand dielectrically insulated from the gate padand the semiconductor body; a source padformed above the first surfaceof the semiconductor bodyand connected to the shielding electrodes; and a plurality of transistor cellseach comprising a gate electrodeconnected to the gate pad.

### RELATED APPLICATION

This application claims priority to German Patent Application No. 102025101520.1, filed on January 16, 2025, entitled “TRANSISTOR DEVICE AND METHOD FOR PRODUCING THEREOF”, which is incorporated by reference herein in its entirety.

### TECHNICAL FIELD

This disclosure relates in general to a transistor device, in particular an insulated gate (IG) transistor device.

### BACKGROUND

An insulated gate transistor device, such as a MOSFET (Metal Oxide Semiconductor Field-Effect Transistor), includes a load path between a source node and a drain node and a gate node. The transistor device switches on or off dependent on a voltage (gate-source voltage) applied between the gate node and the source node. The gate node and the source node are capacitively coupled. Inevitably, the gate node is also capacitively coupled to the drain node. Such coupling of the gate node to the drain node may have the effect that the transistor device switches on in an unintended fashion when a voltage transient of a load path voltage applied between the drain and source nodes occurs. Such unintended switching may occur, particularly, when a gate-drain capacitance, which is the capacitance between the gate node and the drain node, is large relative to the gate-source capacitance, which is the capacitance between the gate node and the source node.

It is desirable to provide an insulated gate transistor device that is robust against unintended switching.

### SUMMARY

One example relates to a transistor device. The transistor device includes a semiconductor body; a drift region of a first doping type in the semiconductor body; a gate pad formed above a first surface of the semiconductor body; a shielding structure arranged between the gate pad and the drift region and including a plurality of shielding electrodes each arranged in a respective shielding trench and dielectrically insulated from the gate pad and the semiconductor body; a source pad formed above the first surface of the semiconductor body and connected to the shielding electrodes; and a plurality of transistor cells each including a gate electrode connected to the gate pad.

Another example relates to a method for producing a transistor device. The transistor device includes a semiconductor body; a drift region of a first doping type in the semiconductor body; a gate pad formed above a first surface of the semiconductor body; a shielding structure arranged between the gate pad and the drift region and including a plurality of shielding electrodes each arranged in a respective shielding trench and dielectrically insulated from the gate pad and the semiconductor body; a source pad formed above the first surface of the semiconductor body and connected to the shielding electrodes; and a plurality of transistor cells each including a gate electrode connected to the gate pad. The method includes forming the shielding electrodes and the gate electrodes by the same process sequence.

Examples are explained below with reference to the drawings. The drawings serve to illustrate certain principles, so that only aspects necessary for understanding these principles are illustrated. The drawings are not to scale. In the drawings the same reference characters denote like features.

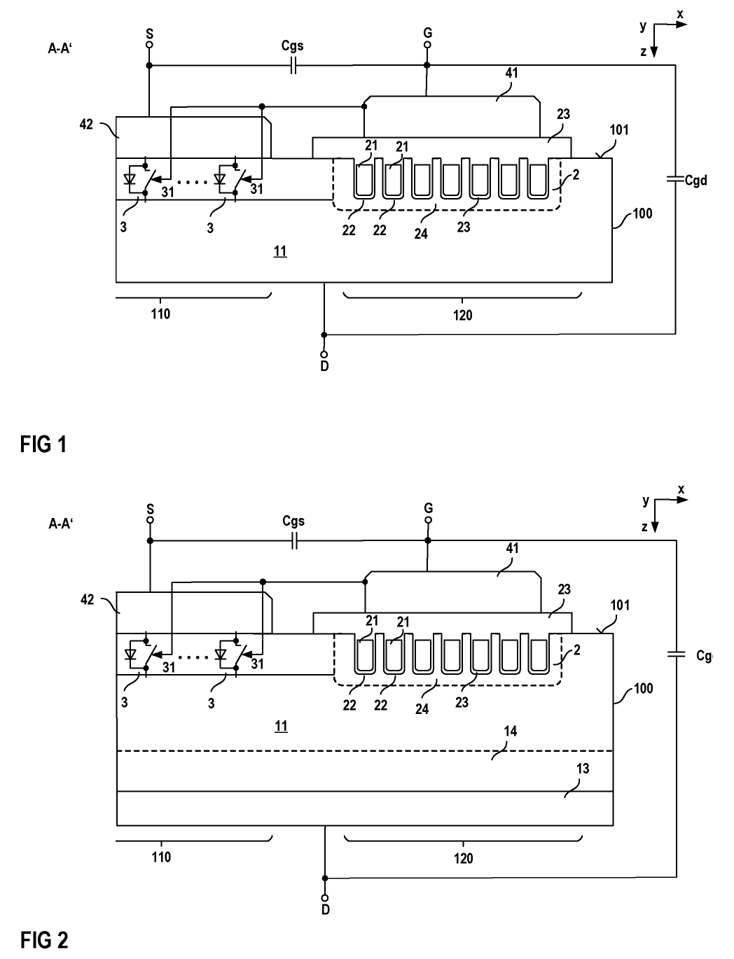

FIG. 1 schematically illustrates a vertical cross-sectional view of a transistor device according to one example, the transistor device including a gate pad, a shielding arrangement between the gate pad and a drift region, a source pad, and a plurality of transistor cells each having a gate electrode connected to the gate pad;

FIG. 2 illustrates a modification of the transistor device according to FIG. 1;

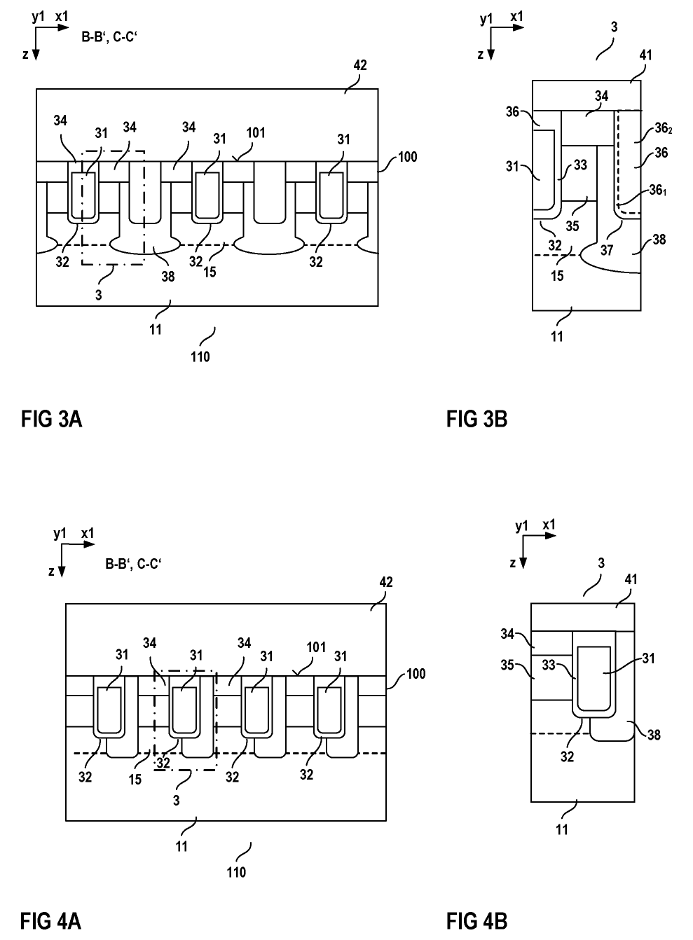

FIGS. 3A-3B illustrate transistor cells according to one example;

FIGS. 4A-4B illustrate transistor cells according to another example;

FIG. 5 shows a top view of the gate pad and a source pad of the transistor device according to one example;

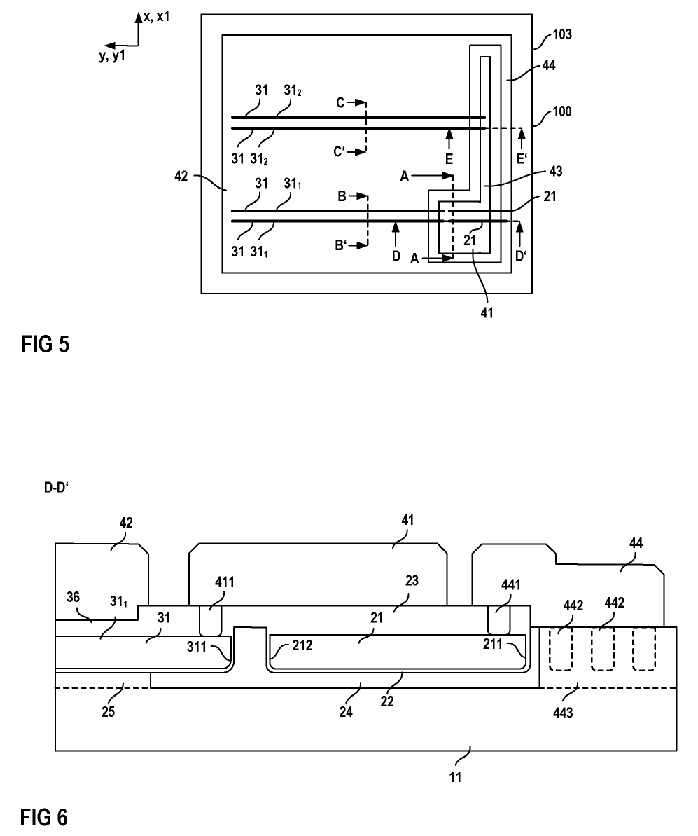

FIG. 6 illustrates one example for connecting shielding electrodes of the shielding arrangement to a source runner and for connecting gate electrodes of the transistor cells to the gate pad;

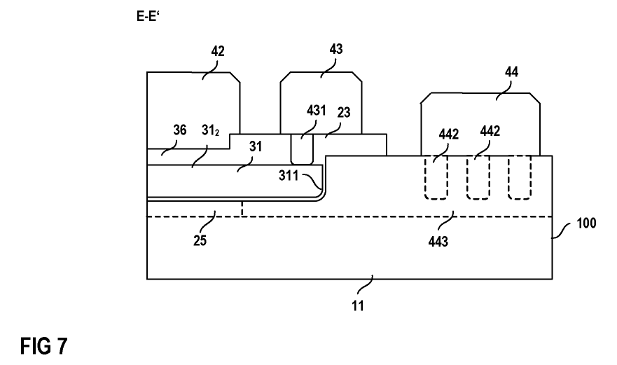

FIG. 7 illustrates one example for connecting the gate electrodes of transistor cells to a gate runner; and

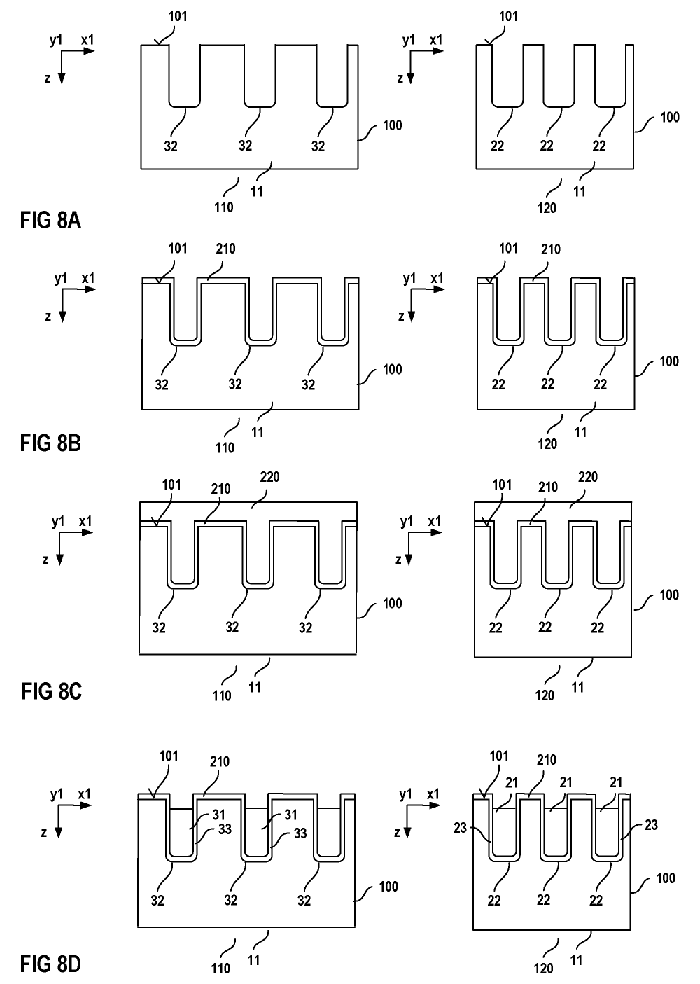

FIGS. 8A-8D illustrate one example of a method for producing the gate electrodes of the transistor cells and the shielding electrodes of the shielding structure by same process steps.

In the following detailed description, reference is made to the accompanying drawings. The drawings form a part of the description and for the purpose of illustration show examples of how the disclosed subject matter may be used and implemented. It is to be understood that the features of the various embodiments described herein may be combined with each other, unless specifically noted otherwise.

One of the examples explained in the following relate to a transistor device. The transistor device includes: a semiconductor body; a drift region of a first doping type in the semiconductor body; a gate pad formed above a first surface of the semiconductor body; a shielding structure arranged between the gate pad and the drift region and including a plurality of shielding electrodes each arranged in a respective shielding trench and dielectrically insulated from the gate pad and the semiconductor body; a source pad formed above the first surface of the semiconductor body and connected to the shielding electrodes; and a plurality of transistor cells each including a gate electrode connected to the gate pad.

According to one example, the gate electrode of each transistor cell is formed in a gate trench extending from a first surface of the semiconductor into the semiconductor body.

According to one example, the transistor device further includes a source runner formed above the first surface of the semiconductor body and connected to the source pad, wherein the shielding electrodes are connected to the source pad through the source runner.

According to one example, the shielding electrodes are elongated electrodes which are spaced apart from each other in a first lateral direction of the semiconductor body and which longitudinally extend in a second lateral direction. The shielding electrodes include a first longitudinal end and a second longitudinal end opposite the first longitudinal end. An end section adjoining the first longitudinal end of each shielding electrode, in the second lateral direction, may protrude from below the gate pad and may be connected to the source runner.

According to one example, the gate electrodes are elongated electrodes which are spaced apart from each other in a third lateral direction and which longitudinally extend in a fourth lateral direction. The third lateral direction may be equal to the first lateral direction, and the fourth lateral direction may be equal to the second lateral direction. The gate electrodes may include a first group of gate electrodes which are spaced apart from the shielding electrodes in the second lateral direction and a second group of gate electrodes which are spaced apart from the shielding electrodes in the first lateral direction, wherein the transistor device may further includes a gate runner connected to the gate pad, wherein the gate electrodes of the first group may directly be connected to the gate pad, and wherein the gate electrodes of the second group may be connected to the gate pad through a gate runner.

According to one example, the transistor device further includes a shielding region of the second doping type adjoining the drift region, wherein the shielding electrodes are embedded in the shielding region.

According to one example, each transistor cell further includes: a gate dielectric dielectrically insulating the gate electrode from the semiconductor body; a source region of the first doping type and connected to the source pad; and a body region of the second doping type adjoining the gate dielectric and the source region and arranged between the source region and the drift region. Each transistor cell may further include a cell shielding region of the second doping type connected to the source pad and, in a vertical direction of the semiconductor body, extending into the drift region. The drift region may include a current spreading region adjoining the gate trenches in the vertical direction and having a higher doping concentration than a remainder of the drift region. The cell shielding region may be spaced apart from the gate trench in the first lateral direction. The cell shielding region may be connected to the source pad through a contact electrode arranged in a trench extending from the first surface into the semiconductor body. Furthermore, the cell shielding region may adjoin one sidewall of the gate trench.

According to one example, the transistor device further includes a drain region of the first doping type coupled to the drift region.

Another example related to a method for producing a transistor device. The transistor device includes: a semiconductor body; a drift region of a first doping type in the semiconductor body; a gate pad formed above a first surface of the semiconductor body; a shielding structure arranged between the gate pad and the drift region and including a plurality of shielding electrodes each arranged in a respective shielding trench and dielectrically insulated from the gate pad and the semiconductor body; a source pad formed above the first surface of the semiconductor body and connected to the shielding electrodes; and a plurality of transistor cells each including a gate electrode connected to the gate pad. The method includes forming the shielding electrodes and the gate electrodes by the same process sequence.

FIG. 1 schematically illustrates a vertical cross-sectional view of a section of a gate-controlled transistor device according to one example. The transistor device is a MOSFET, for example.

The transistor device includes a semiconductor body 100, a drift region 11 of a first doping type in the semiconductor body 100, a gate pad 41 formed above a first surface 101 of the semiconductor body 100, a source pad 42 spaced apart from the gate pad 41 and formed above the first surface 101 of the semiconductor body 100, and a shielding structure 2 arranged between the gate pad 41 and the drift region 11. For example, a doping concentration of the drift region 11 is selected from a range of between 1E15 cm⁻³ and 5E16 cm⁻³ (e.g. in the case of an N-type transistor device). The shielding structure 2 includes a plurality of shielding electrodes 21 each arranged in a respective shielding trench 22, each dielectrically insulated from the gate pad 41 and the semiconductor body 100, and each connected to the source pad 42. However, connections between the source pad 42 and the shielding electrodes 21 are out of view in FIG. 1 and are explained further below. Furthermore, the transistor device includes a plurality of transistor cells 3 that each include a gate electrode 31 connected to the gate pad 41.

FIG. 1 shows a vertical cross-sectional view of a section of the semiconductor body 100 in a vertical section plane that is essentially perpendicular to the first surface 101. Furthermore, the vertical section plane illustrated in FIG. 1 is essentially parallel to a first lateral direction x and a vertical direction z of the semiconductor body 100. The vertical direction z is essentially perpendicular to the first lateral direction x.

The transistor cells 3 are each connected between the source pad 42 and the drift region 11 and are each configured to be in an on-state (conducting state) or an off-state (blocking state) dependent on a voltage (gate-source voltage) applied, during operation of the transistor device, between the gate pad 41 and the source pad 42. The transistor cells 3 can be implemented in various ways and are not illustrated in detail in FIG. 1. Instead, each of the transistor cells 3 is illustrated as an electronic switch with a parallel diode, which represents the functionality of the transistor cells 3 as switches with parallel diodes. The diodes are usually referred to as body diodes. Detailed examples for implementing the transistor cells 3 are explained herein further below.

The semiconductor body 100 includes a monocrystalline semiconductor material. According to one example, the semiconductor body is an SiC (silicon carbide) semiconductor body and includes monocrystalline SiC, such as SiC of the 4H or 6H polytype. According to another example, the semiconductor body is a silicon (Si) semiconductor body and includes monocrystalline silicon.

The shielding electrodes 21 are electrically conducting and include an electrically conducting material. According to one example, the electrically conducting material is doped polysilicon. According to another example, the electrically conducting material is a metal.

Referring to the above, the shielding electrodes 21 are dielectrically insulated from the gate pad 41 and the semiconductor body 100. Referring to FIG. 1, this includes that a dielectric layer 23 is arranged between the shielding electrodes 21 and the semiconductor body 100 in the trenches 22. Furthermore, the gate pad 41 is formed above the dielectric layer 23 and the dielectric layer 23 is arranged between the shielding electrodes 21 and the gate pad 41. The dielectric layer 23 arranged between the shielding electrodes 21 and the gate pad 41 may extend into the trenches 22 and may cover portions of the first surface 101 of the semiconductor body 100.

The dielectric layer 23 insulating the shielding electrodes 21 from the semiconductor body 100 and the gate pad 41 may be a homogeneous layer of the same dielectric material, or may include two or more different layers of different dielectric materials. Examples of the dielectric material include, but are not restricted to, oxides, such as silicon oxides (SiO₂, SiOₓ), silicon nitride oxides (SiNOₓ), HfO₂, or oxides from other elements; nitrides, such as silicon nitrides or oxynitrides; or high-k dielectrics.

According to one example illustrated in dashed lines in FIG. 1, the shielding trenches 22 with the shielding electrodes 21 are embedded in a doped shielding region 24 of the second doping type complementary to the first doping type.

In the following, a region or section 110 of the semiconductor body 100 in which the transistor cells 3 are integrated is referred to as cell region or active device region, and the region or section 120 in which the shielding structure 2 is arranged and above which the gate pad 41 is arranged is referred to as a gate pad region or passive device region.

Referring to FIG. 1, the transistor device may further include a gate node G, a source node S, and a drain node D. The gate node G is a circuit node connected to the gate pad 41 or formed by the gate pad 41, the source node S is a circuit node connected to the source pad 42 by or formed by the source pad 42, and the drain node D is a circuit node connected to the drift region 11. The gate node G and the source node S serve to apply a drive voltage (gate-source voltage) to the transistor cells 3 in order to operate the transistor cells 3 either in the on-state or the off-state. When the transistor cells 3 are in the on-state, a current can flow between the drain node D and the source node S when a respective load path voltage is applied between the drain node D and the source node S. When the transistor cells 3 are in the off-state, the transistor device blocks and prevents a current flow between the drain node D and the source node S, as long as the voltage applied between the drain node D and the source node S is below a voltage blocking capability of the transistor device. The voltage blocking capability, inter alia, is dependent on a doping concentration and a dimension of the drift region 11 in the vertical direction z. According to one example, the drift region 11 is implemented such that the voltage blocking capability is in a range of between 400 V and 8 kV. Specific examples of voltage blocking capabilities include, but are not restricted to, 400 V, 600V, 800V, 1.2 kV, 1.4 kV, 1.7 kV, 2.3 kV, 2.4 kV, 3.3 kV and 6.5 kV.

FIG. 2 shows a transistor device that is based on the transistor device according to FIG. 1 and additionally includes a drain region 13 of the first doping type that is connected to the drain node D. The drain region 13 has a higher doping concentration than the drift region 11. For example, a doping concentration of the drain region 13 is selected from a range of between 5E18 cm⁻³ and 1E19 cm⁻³ (e.g. in the case of an N-type transistor device). The drain region 13 may adjoin a second surface 102 opposite the first surface 101 of the semiconductor body 100. According to one example, the drain region 13 adjoins the drift region 11 so that the drift region 11 is arranged between the first surface 101 and the drain region 13. According to another example, a buffer region 14 of the first doping type is arranged between the drift region 11 and the drain region 13. According to one example, the buffer region 14 has a higher doping concentration than the drift region 11 and a lower doping concentration than the drain region 13. For example, a doping concentration of the buffer region 14 is selected from a range of between 1E16 cm⁻³ and 5E18 cm⁻³ (e.g. in the case of an N-type transistor device).

The transistor device includes a first capacitance Cgs, which is also referred to as gate-source capacitance in the following, between the gate node G and the source node S. Furthermore, the transistor device includes a second capacitance Cgd, which is also referred to as gate-drain capacitance in the following, between the gate node G the drain node D. These first and second capacitances Cgs, Cgd are represented by circuit symbols of capacitors in the examples illustrated in FIGS. 1 and 2.

In the absence of the shielding electrodes 21 connected to the source pad 42 a capacitance would be present between the gate pad 41 and the drift region 11, wherein this capacitance would increase the gate drain-capacitance Cgd of the transistor device. However, a high gate-drain capacitance Cgd, particularly a high gate-drain capacitance Cgd relative to the gate-source capacitance Cgs, is undesirable as this may result in an unintended switching of the transistor device when a transient of a load path voltage applied between the drain node D and the source node S occurs. More specifically, the load path transient may have the effect that the gate-source voltage across the gate-source capacitance Cgs reaches a threshold voltage of the transistor device and, therefore, may cause the transistor device to switch on in unintended fashion.

In a transistor device of the type illustrated in FIGS. 1 and 2, the shielding structure 2 with the shielding electrodes 21 connected to the source pad 41 capacitively shields the gate pad 41 from the drift region 11. In this way, this shielding structure 2 reduces the gate-drain capacitance and increases the gate-source capacitance as compared to a scenario in which there is only a dielectric layer between the gate pad 41 and the drift region 11 and in which the shielding electrodes 21 are omitted. Such increase of the gate-source capacitance Cgs and decrease of the gate-drain capacitance Cgd results in a high robustness of the transistor device against unintended switching when a transient of the load path voltage applied between the drain node D and the source node S occurs.

In addition to the portion of the gate-source capacitance Cgs formed by the gate pad 41 and the shielding structure 2, further portions of the gate-source capacitance Cgs are formed by the transistor cells 3. The gate-drain capacitance Cgd is mainly formed by capacitances between the transistor cells 3 and the drift region 11. This is explained herein further below.

FIGS. 3A-3B and 4A-4B illustrate transistor cells according to different examples, wherein each of FIGS. 3A and 4A shows a vertical cross-sectional view of several transistor cells 3. FIG. 3B shows an enlarged view of one of the transistor cells 3 illustrated in FIG. 3A, and FIG. 4B shows an enlarged view of one of the transistor cells 3 illustrated in FIG. 4A. In each of FIGS. 3A and 4A, only a portion of the transistor cell region 110 of the semiconductor body 100 is illustrated and only that portion of the semiconductor body 100 is illustrated in which the transistor cells 3 are integrated.

Referring to FIGS. 3A-3B and 4A-4B, each transistor cell 3 includes a gate electrode 31, a gate dielectric 33 that dielectrically insulates the gate electrode 33 from the semiconductor body 100, a source region 34 of the first doping type, and a body region 35 of the second doping type. For example, a doping concentration of the source region 34 is selected from a range of between 1E19 cm⁻³ and 1E21 cm⁻³ and the doping concentration of the body region 35 is selected from a range of between 1E17 cm⁻³ and 5E17 cm⁻³ (e.g. in the case of an N-type transistor device). Each of the gate electrodes 31 is arranged in a respective gate trench 32 that extends from the first surface 101 into the semiconductor body 100. In each transistor cell 3, the body region 35 is arranged between the source region 34 and the drift region 11. Furthermore, the body region 35 adjoins the gate dielectric 33. In a conventional way, the gate electrode 31, dependent on the gate-source voltage applied between the gate node G and the source node S during operation of the transistor device, is configured to control a conducting channel in the body region 35 along the gate dielectric 33 between the source region 34 and the drift region 11. The source region 34 of each transistor cell 3 is connected to the source pad 42.

Furthermore, each transistor cell 3 includes a cell shielding region 38 of the second doping type that is connected to the source pad 42 and that may also be referred to as cell shielding region. For example, a doping concentration of the cell shielding region 38 is selected from a range of between 5E19 cm⁻³ and 1E21 cm⁻³ (e.g. in the case of an N-type transistor device). The cell shielding region 38, in the vertical direction, as seen from the first surface 101, extends to below the gate trenches 32, so that cell shielding regions 38 of neighboring transistor cells together with a section of the drift region 11 arranged between the cell shielding regions 38 form a JFET (Junction Field-Effect Transistor) below each gate trench 32. When the transistor device is in the off-state, so that conducting channels in the body regions 35 are interrupted, and when a voltage is applied between the drain and source nodes D, S that reverse biases a PN junction formed between the body regions 35 and the drift region 11, neighboring cell shielding regions 38 pinch of the drift region section formed therebetween and protect the gate dielectric 33 from high electric fields as the voltage applied between the drain and source nodes D, S further increases. This is basically known so that no further explanation is required in this regard.

The gate electrodes 31 are dielectrically insulated from the source pad 42 by a dielectrically insulating layer 36. The dielectrically insulating layer 36 may include the same type of material as the gate dielectric 33, for example.

In the transistor cells illustrated in FIGS. 3A-3B, the cell shielding regions 38 are spaced apart from the gate trenches 32 in the first lateral direction x and each gate trench 32 adjoins a body region 35 at opposite trench sidewalls. In this example, the gate electrodes 31 of two transistor cells are formed by the same electrode arranged in one gate trench 32. Furthermore, the cell shielding region 38 of two transistor cells 3 are formed by the same doped region of the second doping type. Furthermore, in this example, the cell shielding region 38 is electrically connected to the source pad 42 through a contact electrode 36 that extends from the first surface 101 of the semiconductor body 100 into the semiconductor body 100.

The contact electrode 36 includes an electrically conducting material such as a metal. According to one example, the contact electrode 36 is a homogeneous electrode made of the same electrically conducting material, such as tungsten (W). According to another example illustrated in dashed lines in FIG. 3B, the contact electrode 36 includes two or more electrically conducting layers, such as a first layer 36₁lining a bottom and sidewalls of a contact trench in which the contact electrode 36 is formed and a second layer 36₂ filling a residual trench that remains after forming the first layer 36₁. According to one example, the first layer 36₁ is a titanium (Ti) layer and the second layer 36₂ is a tungsten (W) layer.

In the transistor cells 3 illustrated in FIGS. 4A-4B, each gate trench 32 adjoins a respective body region 35 at only a first sidewall. The cell shielding region 38 adjoins a second sidewall opposite the first sidewall of the gate trench 32. In this example, a conducting channel in the body region 35 can be formed only along one of the two sidewalls of each gate trench 32. In the vertical direction z, the cell shielding regions 38 extend to source pad 42. Alternatively (not illustrated) the transistor cells 3 illustrated in FIGS. 4A-4B each include a contact electrode that connects the respective cell shielding region 38 to the source pad 42.

Referring to the above, a portion of the gate-source capacitance is formed between the transistor cells 3 and the source pad 42. More specifically, portions of the gate-source capacitance are formed by the gate electrodes 31, the gate dielectrics, and the source regions 34 dielectrically insulated from the gate electrode 31 by the gate dielectrics 33. Furthermore, portions of the gate-drain capacitance are formed by the gate electrodes 31, the gate dielectrics 33 arranged between the gate electrodes 31 and the drift region 11, and the drift region.

The transistor device can be implemented as an N-type transistor device or as a P-type transistor device. In an N-type transistor device, the doped regions of the first doping type, such as the source regions 34, the drift region 11, the drain region 13, and the optional buffer region 14, are N-type regions and the doped regions of the second doping type, such as the body regions 35, are P-type regions. In a P-type transistor device, the doped regions of the first doping type are P-type regions and the doped regions of the second doping type are N-type regions.

According to one example (not illustrated), the transistor device is implemented as a superjunction device. In this example, the transistor device includes a plurality of compensations regions of the second doping that are arranged in the drift region 11, are connected to the source node S, and, in the vertical direction z, extend from below the transistor cells 3 to the drain region 13 or the optional buffer region 14. The compensation regions may adjoin the cell shielding regions 38 in order to be connected to the source node S via the cell shielding regions 38. A doping concentration of the compensation regions is in the same range as the doping concentration of the drift region 11, for example.

It should be noted that FIGS. 3A-3B and 4A-4B illustrates only two of a variety of different examples for implementing the transistor cells 3 that each include a trench electrode 31. In each example, the trench gate electrodes 31 of the transistor cells number 3 and the shielding electrodes 21 of the shielding structure 2 can be formed by the same process, so that no additional process steps are required for forming the shielding electrodes 21. This results in a high efficiency of the method for producing the transistor device.

Referring to FIGS. 3A-3B and 4A-4B, the drift region 11 may include a current spreading region 15 that has a higher doping concentration than a remainder of the drift region 11. The current spreading region 15 helps to reduce an on-resistance of the transistor device, which is the electrical resistance between the drain and source nodes D, S in the on-state of the transistor cells 3. According to one example, the current spreading region 15 adjoins the body regions 35 and is arranged between neighboring cell shielding regions 38.

Referring to FIGS. 1 and 2, the shielding trenches 22 with the shielding electrodes 21 are spaced apart from each other in a lateral direction x of the semiconductor body 100. The lateral direction in which the shielding electrodes 21 are spaced apart from each other is the first lateral direction x of the semiconductor body 100 in this example. Furthermore, the shielding electrodes 21 are elongated electrodes which longitudinally extend in a second lateral direction y. According to one example, the second lateral direction y is at least approximately perpendicular to the first lateral direction x.

Referring to FIGS. 3A and 4A, the gate trenches 32 with the gate electrodes 31 are spaced apart from each other in a third lateral direction x1 of the semiconductor body 100. According to one example, the gate electrodes 31 are elongated electrodes which longitudinally extend in a fourth lateral direction y1 which is at least approximately perpendicular to the third lateral direction x1.

According to one example, the shielding electrodes 21 and the gate electrodes 31 have the same orientation. That is, the first lateral direction x, in which the shielding electrodes 21 are spaced apart from each other, equals the third lateral direction x1, in which the gate electrodes 31 are spaced apart from each other. Equivalently, the second lateral direction y, in which the shielding electrodes 21 longitudinally extend, equals the fourth lateral direction y1, in which the gate electrodes 31 longitudinally extend.

FIG. 5 schematically illustrates a top view of a transistor device with elongated shielding electrodes 21 and elongated gate electrodes 31 that have the same orientation. More specifically, FIG. 5 shows a top view of the gate pad 41 and the source pad 42 of a transistor device according to one example. Furthermore, the position and orientation of some shielding electrodes 21 arranged in the semiconductor body 100 in shielding trenches 22 below the gate pad 41 and the position and orientation of some gate electrodes 31 arranged in gate trenches 32 in the semiconductor body 100 below the source pad 42 is illustrated by bold lines.

The transistor device illustrated in FIG. 5 includes a gate runner 42 that is formed above the semiconductor body 100 and is connected to the gate pad 41. In this example, the transistor cells 3 include a first group of transistor cells that have their gate electrodes 31 directly connected to the gate pad 41 and a second group of transistor cells 3 that have their gate electrodes 31 directly connected to the gate runner 43, so that the gate electrodes of the transistor cells number 3 of the second group are connected to the gate pad 41 through the gate runner 43. In FIG. 5, gate electrodes of the transistor cells of the first group have reference number 31₁ and the gate electrodes of the transistor cells of the second group have reference number 31₂.

Referring to FIG. 5, the gate runner 43 is elongated and longitudinally extends in the first lateral direction x, which is the direction in which the shielding electrodes 21 and the gate electrodes 31 are spaced apart from each other. In the example illustrated in FIG. 5, the gate pad 41 is arranged essentially above a corner region of the semiconductor body 100 and the transistor device includes only one gate runner 43. According to another example (not illustrated) the gate pad 41 is arranged essentially in the middle between two opposite sides of the semiconductor body 100 and the transistor device includes two gate runners each extending in the first lateral direction x, but on opposite sides of the gate pad.

It should be noted that “first lateral direction x” and “second lateral direction y” as well as “third lateral direction x1” and “fourth lateral direction y1” denote lateral orientations, so that each of these directions represents a certain direction and the corresponding opposite direction.

The cross-sectional view of the gate pad region 120 and of an adjoining portion of the cell region 110 illustrated in FIG. 1 corresponds to a cross-sectional view in section plane A-A’ illustrated in FIG. 5 that cuts through the gate pad 41 and a portion of the source pad 42 and regions of the semiconductor body 100. The cross-sectional views of the transistor cells 3 illustrated in FIGS. 3A and 4A correspond to cross-sectional views in section plane B-B’ and C-C’ illustrated in FIG. 5, wherein section plane B-B’ cuts through a portion of the source pad 42 and transistor cells 3 of the first group and section plane C-C’ cuts through a portion of the source pad 42 and transistor cells 3 of the second group.

Referring to the above, the gate electrodes 31₁ of the first group of transistor cells 3 are directly connected to the gate pad 41. For this, the gate electrodes 31₁, in their longitudinal direction extend to below the gate pad 41. One example for connecting the gate electrodes 31₁ of the first group to the gate pad 41 is illustrated in FIG. 6 and explained herein further below. Furthermore, the gate electrodes 31₂ of the second group of transistor cells 3 are directly connected to the gate runner 44. For this, the gate electrodes 31₂, in their longitudinal direction, extend to below the gate runner 44. One example for connecting the gate electrodes 31₂ of the second group to the gate pad 41 is illustrated in FIG. 7 and explained herein further below.

Referring to the above, the shielding electrodes 21 are connected to the source pad 42. In the example illustrated in FIG. 5, the transistor device further includes a source runner 44 that is connected to the source pad 42. The source pad 42 and the source runner 44 define an opening in which the gate pad 41 and the gate runner 43 are arranged. Furthermore, the gate runner 44 is arranged between the gate pad 41 and a first edge surface 103 of the semiconductor body 100. In this example, the shielding electrodes 21 are connected to the source runner 44, so that the shielding electrodes 21 are connected to the source pad 42 through the source runner 44. For connecting the shielding electrodes 21 to the source runner 44, the shielding electrodes 21, in their longitudinal direction extend from below the gate pad 41 beyond the gate pad 41 to below the source runner 44.

FIG. 6, illustrates one example for connecting the gate pad 41 to the gate electrodes 31₁ of the first group and for connecting the source runner 44 to the shielding electrodes 21. FIG. 6 shows a vertical cross-sectional view in section plane D-D’ illustrated in FIG. 5. Section plane D-D’ cuts through one shielding electrode 21 and a portion of a neighboring gate electrode 31 in longitudinal directions of the gate electrode 21 and the shielding electrode 31. Furthermore, section plane D-D’ cuts through the gate pad 41, the source runner 44, a portion of the source pad 42 and the semiconductor body 100.

Referring to FIG. 6, the shielding electrode 21 includes a first longitudinal end 211 and a second longitudinal end 212, wherein the first longitudinal end terminates a section of the shielding electrode 21 that extends beyond the gate pad 41 in the longitudinal direction to below the source runner 44. A first end section, which is a section of the shielding electrode 21 adjoining the first longitudinal end 211, is connected to the source runner 44 through a contact via 441 that extends, in the vertical direction z, from the source runner 44 through the dielectric layer 23 arranged above the shielding electrode 21 down to the shielding electrode 21. The second longitudinal end 212 of the shielding electrode 21 faces the neighboring gate electrode 31 and is spaced apart from the gate electrode 31. Furthermore, the second longitudinal end 212 is arranged below the gate pad 41.

Referring to FIG. 6, the gate electrode 31 has a first longitudinal end 311 which faces the second longitudinal end 212 of the neighboring shielding electrode 21. The first longitudinal end of the gate electrode 31 and an end section of the gate electrode 31, which is a section of the gate electrode 31 adjoining the first longitudinal end 311, are arranged below the gate pad 41. The end section of the gate electrode 31 is connected to the gate pad 41 through an electrically conducting via 411. Via 411, in the vertical direction z, extends from the gate pad 41 through the dielectric layer 23 down to the gate electrode 31. The dielectric layer 23 separating the shielding electrode 21 from the gate pad 41 and the gate electrode 31 from the gate pad 41.

Referring to the above, the source runner 44 may be arranged between the gate pad 41 and a first edge surface 103 of the semiconductor body 100. Optionally, as illustrated in dashed lines in FIG. 6, the source runner 44 is connected to the semiconductor body 100 in the edge region of the semiconductor body 100. The edge region is a region of the semiconductor body 100 below the source runner 44. For this, one or more contact plugs 442 extend from the source runner 44 into an edge termination region 443 of the second doping type. The edge termination region 443 may adjoin the drift region 11 of the first doping type.

Referring to the above, the gate electrodes 31₂ of the second group of transistor cells 3 are connected to the gate runner 43. One example for connecting the gate runner 43 to the gate electrodes 31₂ of the transistor cells of the second group is illustrated in FIG. 7.

FIG. 7 shows a vertical cross-sectional view in section plane E-E’ illustrated in FIG. 5. Section plane E-E’ that cuts through a portion of one gate electrode 31₂ a portion of the source pad 43, the gate runner 43, one shielding electrode 21 and a portion of a neighboring gate electrode 31 in longitudinal directions of the gate electrode 21 and the shielding electrode 31. Referring to FIG. 7, the gate electrode 31₂includes a first longitudinal end 311 and an end section adjoining the first longitudinal and 311. The end section is at least partially arranged below the gate runner 43 and is electrically connected to the gate runner 43 through an electrically conducting via 431, Via 431 extends through the dielectrically insulating layer 23 separating the gate electrode 31₂ from the gate pad 41 (which is not illustrated in FIG. 7) and also from the gate runner 43. In the same way as adjacent to the gate pad 41, the source runner 44 may be connected to the edge termination region 443 arranged in the edge region of the semiconductor body 100.

As explained above, the shielding electrodes 21 are arranged in shielding trenches 22 at least partially below the gate pad 41 and the gate electrodes 31 may be arranged in gate trenches 32 at least partially below the source pad 42. Implementing both the shielding electrodes 21 and the gate electrode 31 as trench electrodes makes it possible to produce the transistor device in an efficient way as the shielding electrodes 21 and the gate electrodes 31 can be formed by the same process (method) sequence. One example of a method for producing the shielding electrodes 21 and the gate electrodes 31 is explained with reference to FIGS. 8A-8D in the following.

Each of FIGS. 8A-8D shows a vertical cross-sectional view of one portion of the semiconductor body 100 in the transistor cell region 110 and the gate pad region 120. In the semiconductor body 100, only the drift region 11 is illustrated. Further doped regions, such as the source and body regions 34, 35 of the transistor cells 3 or the shielding region 24 in the gate pad region 120, are not illustrated. These doped regions may be formed for or after forming the shielding electrodes 21 and the gate electrodes 31.

Referring to FIG. 8A, the method includes forming the shielding trenches 22 and the gate trenches 32 by the same process steps. Forming the trenches 22, 32 may include an anisotropic etching process using an etch mask (not illustrated) formed on top of the first surface 101.

Referring to FIG. 8B, the method further includes forming a dielectric layer 210 at least along sidewalls and bottoms of the shielding trenches 22 and the gate trenches 32. Portions of the dielectric layer 210 in the gate trenches 32 form the gate dielectrics 33 of the transistor cells number 3 in the finished device, and portions of the dielectric layer 210 in the shielding trenches 22 form a portion of the dielectric layer 23 separating the shielding electrodes 21 from the semiconductor body 100 in the finished device.

Forming the dielectric layer 210 may include a deposition process in which the dielectric layer 210 is deposited on sidewalls and bottoms of the trenches 22, 32 and the first surface 101 between the trenches. According to one example, the dielectric layer 210 is a homogeneous layer of only one dielectric material, such as silicon oxide. According to another example, the dielectric layer 210 includes two or more sub-layers of different dielectric materials formed one above the other.

According to one example, the dielectric layer 210 is formed to be thicker at the trench bottoms of the trenches 22 than at the sidewalls of the trenches 22, so that, in the finished device, the dielectric layer 23 in the trenches 22 is thicker at the trench bottoms than at the sidewalls. In this example, the dielectric layer 210 includes a HDP (High Density Plasma) oxide, for example, which can be formed in a specific type of deposition process. Similar to the trench bottoms, the dielectric layer 210 may be thicker on top of the first surface 101 than at the trench sidewalls.

Referring to FIG. 8C, the method further includes forming an electrode layer 220 at least in the shielding trenches 22 and the gate trenches 32. According to one example illustrated in FIG. 8C, the electrode layer 220 is formed to completely fill the shielding trenches 22 and the gate trenches 32 on top of the dielectric layer 210. Furthermore, the electrode layer 220 is formed above the first surface 101.Forming the electrode layer 220 may include a deposition process.

Referring to FIG. 8D, the method further includes forming the shielding electrodes 21 in the shielding trenches 22 and the gate electrodes 31 in the gate trenches 32 based on the electrode layer 220. This may include an etching process in which the electrode layer 220 is removed from above the first surface 101. According to one example (not illustrated) the etching process stops when the electrode layer 220 has been removed from above the first surface 101. According to another example (illustrated in FIG. 8D), the etching process continues after the electrode layer 2020 has been removed from above the first surface 101, so that the shielding electrodes 21 in the shielding trenches 22 and the gate electrodes 31 in the gate trenches 32 are recessed relative to the first surface 101.

After forming the shielding electrodes 21 and the gate electrodes 31 the remainder of the dielectric layer 23 separating the shielding electrodes 21 from the gate pad 41 in the finished device and the insulating layer 36 separating the gate electrodes 31 from the source pad 42 in the finished device may be formed. This may include one deposition process in which a dielectrically insulating layer is deposited that forms the dielectric layer 23 between the shielding electrodes 21 and the gate pad 41 and insulating layer between the gate electrodes 31 and the source pad 42.

1. A transistor device, comprising:
a semiconductor body;
a drift region of a first doping type in the semiconductor body;
a gate pad formed above a first surface of the semiconductor body;
a shielding structure arranged between the gate pad and the drift region and comprising shielding electrodes each arranged in a respective shielding trench and dielectrically insulated from the gate pad and the semiconductor body;
a source pad formed above the first surface of the semiconductor body and connected to the shielding electrodes; and
transistor cells each comprising a gate electrode connected to the gate pad.

2. The transistor device of claim 1,
wherein the gate electrode of each transistor cell is formed in a gate trench extending from a first surface of the semiconductor body into the semiconductor body.

3. The transistor device of claim 2, further comprising:
a source runner formed above the first surface of the semiconductor body and connected to the source pad,
wherein the shielding electrodes are connected to the source pad through the source runner.

4. The transistor device of claim 3,
wherein the shielding electrodes are elongated electrodes which are spaced apart from each other in a first lateral direction of the semiconductor body and which longitudinally extend in a second lateral direction.

5. The transistor device of claim 4,
wherein each of the shielding electrodes comprises a first longitudinal end and a second longitudinal end opposite the first longitudinal end.

6. The transistor device of claim 5,
wherein an end section adjoining the first longitudinal end of each shielding electrode, in the second lateral direction, protrudes from below the gate pad and is connected to the source runner.

7. The transistor device of claim 4,
wherein the gate electrodes are elongated electrodes which are spaced apart from each other in a third lateral direction and which longitudinally extend in a fourth lateral direction.

8. The transistor device of claim 7,
wherein the third lateral direction equals the first lateral direction, and
wherein the fourth lateral direction equals the second lateral direction.

9. The transistor device of claim 8,
wherein the gate electrodes comprises a first group of gate electrodes which are spaced apart from the shielding electrodes in the second lateral direction and a second group of gate electrodes which are spaced apart from the shielding electrodes in the first lateral direction,
wherein the transistor device further comprises a gate runner connected to the gate pad,
wherein the gate electrodes of the first group are directly connected to the gate pad, and
wherein the gate electrodes of the second group are connected to the gate pad through a gate runner.

10. The transistor device of claim 1, further comprising:
a shielding region of a second doping type adjoining the drift region,
wherein the shielding electrodes are embedded in the shielding region.

11. The transistor device of claim 1, wherein each transistor cell further comprises:
a gate dielectric dielectrically insulating the gate electrode from the semiconductor body;
a source region of the first doping type and connected to the source pad; and
a body region of a second doping type adjoining the gate dielectric and the source region and arranged between the source region and the drift region.

12. The transistor device of claim 11, wherein each transistor cell further comprises:
a cell shielding region of the second doping type connected to the source pad and, in a vertical direction of the semiconductor body, extending into the drift region.

13. The transistor device of claim 12,
wherein the drift region comprises a current spreading region adjoining a gate trench in the vertical direction and having a higher doping concentration than a remainder of the drift region.

14. The transistor device of claim 12,
wherein the cell shielding region is spaced apart from a gate trench in a first lateral direction.

15. The transistor device of claim 14,
wherein the cell shielding region is connected to the source pad through a contact electrode arranged in a trench extending from the first surface into the semiconductor body.

16. The transistor device of claim 12,
wherein the cell shielding region adjoins one sidewall of a gate trench.

17. The transistor device of claim 1, further comprising:
a drain region of the first doping type coupled to the drift region.

18. A method for producing a transistor device,
wherein the transistor device comprises:
a semiconductor body;
a drift region of a first doping type in the semiconductor body;
a gate pad formed above a first surface of the semiconductor body;
a shielding structure arranged between the gate pad and the drift region and comprising shielding electrodes each arranged in a respective shielding trench and dielectrically insulated from the gate pad and the semiconductor body;
a source pad formed above the first surface of the semiconductor body and connected to the shielding electrodes; and
transistor cells each comprising a gate electrode connected to the gate pad, and
wherein the method comprises:
forming the shielding electrodes and the gate electrodes by the same process sequence.

19. A method, comprising:
forming a semiconductor body;
forming a drift region of a first doping type in the semiconductor body;
forming a gate pad above a first surface of the semiconductor body;
forming a shielding structure arranged between the gate pad and the drift region and comprising shielding electrodes each arranged in a respective shielding trench and dielectrically insulated from the gate pad and the semiconductor body;
forming a source pad above the first surface of the semiconductor body and connected to the shielding electrodes; and
forming transistor cells each comprising a gate electrode connected to the gate pad.

20. The method of claim 19, further comprising:
forming a source runner above the first surface of the semiconductor body.
